(19) United States
(12) Patent Application Publication
(10) Pub. No.: US 2025/0006565 A1
(43) Pub. Date: Jan. 2, 2025

(54) ELECTRONIC COMPONENT HOUSING PACKAGE AND ELECTRONIC MODULE

(71) Applicant: KYOCERA Corporation, Kyoto-shi (JP)

(72) Inventors: Tomoya TABUCHI, Kyoto-shi (JP); Toshiyuki MATSUMOTO, Kyoto-shi (JP)

(73) Assignee: KYOCERA Corporation, Kyoto-shi (JP)

(21) Appl. No.: 18/756,756

(22) Filed: Jun. 27, 2024

Related U.S. Application Data
(60) Provisional application No. 63/511,011, filed on Jun. 29, 2023.

(51) Int. Cl. H01L 23/047; H01L 23/08; H01L 23/10

(52) U.S. Cl. CPC H01L 23/047; H01L 23/08; H01L 23/10

(57) ABSTRACT

To provide an electronic component housing package and an electronic module enabling an increase in electrode terminals. An electronic component housing package includes a base, a frame, and a wiring conductor. The base includes a first region. The frame is positioned on the base and surrounds the first region. The frame includes a first frame side surface. The wiring conductor is positioned on a surface of the frame. The frame includes a first projecting portion projecting outward from the first frame side surface in a first direction. The wiring conductor includes a first conductor and a second conductor. The second conductor is spaced outward from the first conductor in the first direction. The first conductor and the second conductor are positioned on the first projecting portion and on a same plane.

### TECHNICAL FIELD

The present disclosure relates to an electronic component housing package and an electronic module.

### BACKGROUND ART

A device housing package according to the related art is described in, for example, Patent Literature 1.

### CITATION LIST

### Patent Literature

[Patent Literature 1] International Publication No. WO2015/012405

### SUMMARY OF THE INVENTION

### Solution to Problem

In an embodiment, (1) an electronic component housing package includes a base, a frame, and a wiring conductor. The base includes a first region. The frame is positioned on the base and surrounds the first region. The frame includes a first frame side surface. The wiring conductor is positioned on a surface of the frame. The frame includes a first projecting portion projecting outward from the first frame side surface in a first direction. The wiring conductor includes a first conductor and a second conductor. The second conductor is spaced outward from the first conductor in the first direction. The first conductor and the second conductor are positioned on the first projecting portion and on a same plane.

(2) In the electronic component housing package according to (1) described above, when a direction along the first frame side surface is a second direction, a plurality of the first conductors is arranged in the second direction, and a plurality of the second conductors is arranged in the second direction.

(3) In the electronic component housing package according to (1) or (2) described above, the frame includes a second frame side surface and a second projecting portion. The second frame side surface faces the first frame side surface in the first direction. The second projecting portion projects outward from the second frame side surface in the first direction. The wiring conductor includes a third conductor and a fourth conductor. The fourth conductor is spaced from the third conductor in the first direction. The third conductor and the fourth conductor are positioned on the second projecting portion and on a same plane.

(4) In the electronic component housing package according to any one of (1) to (3) described above, the base overlaps the first projecting portion in plan view.

(5) In the electronic component housing package according to (4) described above, the base includes a first base side surface positioned along the first frame side surface. The first projecting portion includes a first-projecting-portion side surface positioned along the first frame side surface. A distance L1 from the first frame side surface to the first base side surface in the first direction is equal to or greater than one-half of a distance L2 from the first frame side surface to the first-projecting-portion side surface in the first direction.

(6) In the electronic component housing package according to (4) or (5) described above, the base overlaps the first conductor in plan view.

(7) In the electronic component housing package according to (6) described above, the base is spaced from the second conductor in plan view.

(8) In the electronic component housing package according to any one of (1) to (7) described above, the frame is made of a ceramic material.

(9) In the electronic component housing package according to any one of (1) to (8) described above, the base is made of a metal material.

(10) In the electronic component housing package according to any one of (1) to (9) described above, the frame includes a first upper surface. The first projecting portion includes a second upper surface. The first conductor and the second conductor are positioned on the second upper surface. The first upper surface is flush with the second upper surface.

(11) In the electronic component housing package according to (10) described above, the first upper surface includes a joining region. A lid body or a seal ring is joined to the joining region. The joining region is spaced from the first conductor and the second conductor.

(12) In the electronic component housing package according to (11) described above, the first projecting portion includes a first-projecting-portion side surface positioned along the first frame side surface. A distance D1 between the joining region and the first conductor in the first direction is greater than a distance D2 between the first-projecting-portion side surface and the second conductor in the first direction.

(13) The electronic component housing package according to any one of (1) to (12) described above further includes a transparent member joined to the base. The base includes a through-hole extending through the base in the first region. The transparent member overlaps the through-hole.

(14) The electronic component housing package according to any one of (1) to (13) further includes a first connector joined to the base. The first connector includes at least two or more wiring terminals. The first connector is positioned on the first projecting portion. Each of the at least two or more wiring terminals is electrically connected to a respective one of the first conductor and the second conductor.

(15) In an embodiment, an electronic module includes an electronic component, a lid body and the electronic component housing package according to any one of (1) to (14) described above. The electronic component is positioned on the first region. The lid body is positioned on the frame.

### BRIEF DESCRIPTION OF DRAWINGS

FIG. 1 is a perspective view of an electronic component housing package according to an embodiment.

FIG. 2 is a top plan view of the electronic component housing package according to an embodiment.

FIG. 3 is a bottom plan view of the electronic component housing package according to an embodiment.

FIG. 4 is a sectional view of the electronic component housing package illustrated in FIG. 2 taken along line IV-IV.

FIG. 5 is a perspective view of the electronic component housing package according to an embodiment to which connectors are connected.

FIG. 6 is a perspective view of an electronic component housing package according to another embodiment.

FIG. 7 is an exploded perspective view of an electronic module according to an embodiment.

### DESCRIPTION OF THE INVENTION

Patent Literature 1 describes a known device housing package. In recent years, the number of electronic components housed in device housing packages has increased, and this has led to an increase in the required number of electrode terminals. The device housing packages are required not only to include a greater number of electrode terminals but also to be smaller and have a reduced height.

### <Structure of Electronic Component Housing Package>

The following describes some exemplary embodiments with reference to the drawings. Note that any direction of an electronic component housing package may be upward or downward. For convenience, a Cartesian coordinate system xyz is defined, and a positive z-direction is defined as upward. In the present disclosure, the concept of plan view includes see-through plan view.

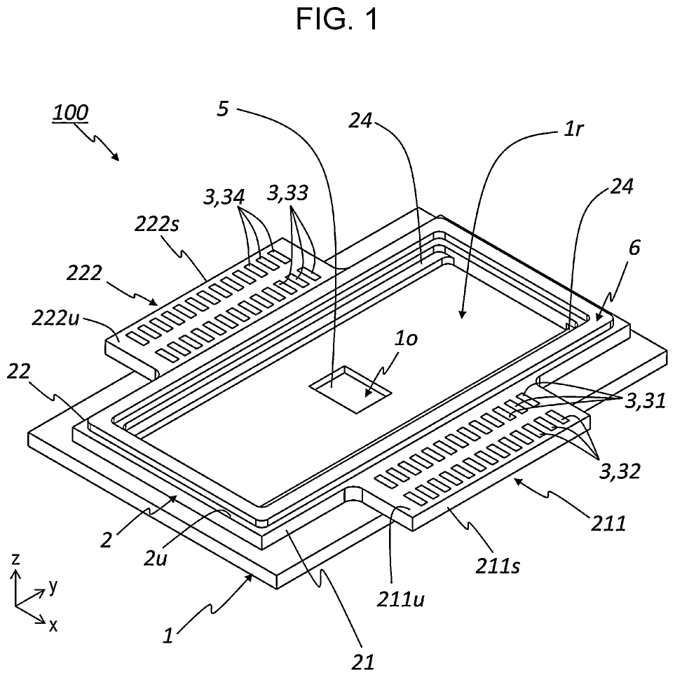

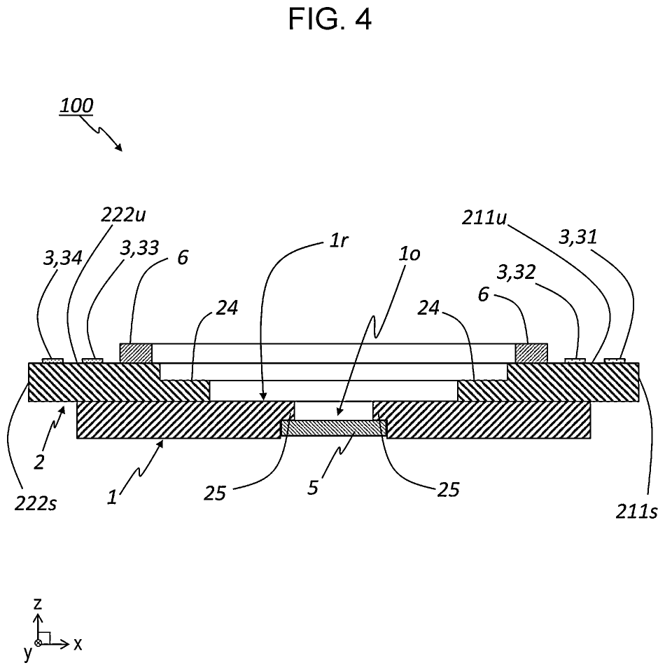

As illustrated in FIGS. 1 to 5, in an embodiment, an electronic component housing package 100 includes a base 1, a frame 2, and wiring conductors 3.

The base 1 includes a first region 1r. An electronic component 9 described below may be directly or indirectly mounted on the first region 1r. The base 1 is, for example, rectangular in plan view, and may have a size of 5 mm×10 mm to 25 mm×50 mm and a thickness of 0.5 mm to 20 mm. The base 1 may have a rectangular shape with rounded or chamfered corners. This structure can reduce the stress applied to the corners of the base 1.

The material of the base 1 may be, for example, a metal material, such as copper, iron, tungsten, molybdenum, nickel, or cobalt, or an alloy containing these metal materials. In this case, the base 1 may be a single metal plate or a multilayer body including a plurality of metal plates. When the metal material of the base 1 is the above-described metal material, a plating layer may be formed on a surface of the base 1 to reduce oxidation corrosion. The plating layer may be formed by electroplating or electroless plating and made of nickel, gold, or the like. Note that the base 1 described herein as being made of a metal material may be made substantially of the metal material, and the base 1 may, for example, contain a non-metal material inevitable in manufacturing.

The material of the base 1 may also be an insulating material, for example, a ceramic material, such as an aluminum oxide-based sintered body, a mullite-based sintered body, a silicon carbide-based sintered body, an aluminum nitride-based sintered body, a silicon nitride-based sintered body, or a glass ceramic.

The frame 2 is positioned on the base 1 and surrounds the first region 1r. The material of the frame 2 may be, example, a ceramic material, such as an aluminum oxide-based sintered body, a mullite-based sintered body, a silicon carbide-based sintered body, an aluminum nitride-based sintered body, or a silicon nitride-based sintered body, or a dielectric material, such as a glass ceramic material or a glass epoxy material.

The material of the frame 2 may also be, for example, a resin and/or a metal. The resin may be one type of resin selected from the group including epoxy resin, phenolic resin, unsaturated polyester resin, polytetrafluoroethylene resin, urea resin, melamine resin, and thermosetting polyimide resin. Note that metal plating, such as nickel plating or gold plating, may be formed on a surface of the frame 2.

When the base 1 and the frame 2 are made of the same material (for example, aluminum nitride-based sintered body), the base 1 and the frame 2 may be formed integrally.

When the frame 2 is a multilayer body, metal wires may be positioned on an inner layer and a surface of the frame 2. The metal wires may be electrically connected to the wiring conductors 3.

The frame 2 includes a first frame side surface 21. The frame 2 includes a first projecting portion 211 projecting outward from the first frame side surface 21 in a first direction (in other words, x direction in the drawings; in the following description, the first direction is referred to also as the x direction for convenience). In the present disclosure, outward is a direction away from the first region 1r. Note that the frame 2 may include a first upper surface 2u described below. In an embodiment, the first projecting portion 211 is shaped such that a portion of the first frame side surface 21 projects outward.

The first projecting portion 211 may also be shaped such that the entirety of the first frame side surface 21 projects. In this case, the first frame side surface 21 coincides with a first-projecting-portion side surface 211s described below.

As illustrated in FIGS. 1, 2, and 4, the frame 2 may be step-shaped in cross-section and include a shelf portion 24 projecting inward. In the present disclosure, inward is a direction toward the first region 1r. When the frame 2 includes the shelf portion 24, one or more wiring conductors 3 may be positioned also on the frame 2. The one or more wiring conductors 3 positioned on the shelf portion 24 may be electrically connected to one or more first conductors 31 and/or one or more second conductors 32. The one or more wiring conductors 3 positioned on the shelf portion 24 may each be electrically connected to the electronic component 9 by a bonding wire or the like.

The wiring conductors 3 are positioned on a surface of the frame 2. The wiring conductors 3 include the first conductors 31 and the second conductors 32. Examples of the material of the wiring conductors 3 include metal materials, such as gold, silver, copper, nickel, tungsten, molybdenum, and manganese. The wiring conductors 3 may be formed by sintering metal paste on the surface of the frame 2, or by thin film formation technology, such as vapor deposition or sputtering.

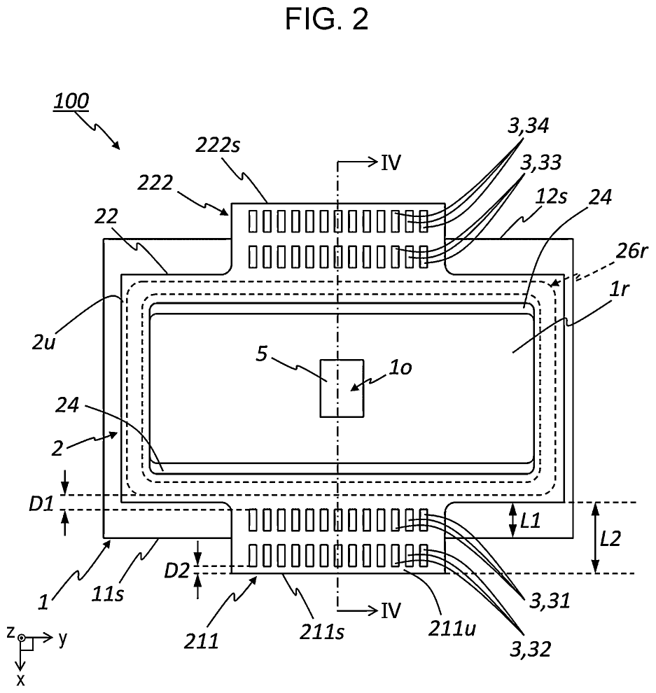

As illustrated in FIG. 2 and other drawings, the first conductors 31 and the second conductors 32 may have rectangular shapes including long sides along the x direction. The first conductors 31 and the second conductors 32 may have the same or different shapes.

The first conductors 31 and the second conductors 32 may be electrically connected to the electronic component 9 described below. This structure enables electrical connection between the electronic component 9 and the inside/outside of the electronic component housing package 100 while protecting the electronic component 9. The structure also enables airtight sealing of the electronic component 9.

The second conductors 32 are spaced outward from the first conductors 31 in the x direction. In other words, the second conductors 32 are closer to the first-projecting-portion side surface 211s than the first conductors 31. In an embodiment, as illustrated in FIGS. 1 and 2 and other drawings, the second conductors 32 are aligned with respective ones of the first conductors 31 in the x direction. However, the second conductors 32 are not limited to this. That is, as long as the second conductors 32 are separated from the first conductors 31 in the x direction, the second conductors 32 may be shifted from the respective first conductors 31 in the y direction.

The first conductors 31 and the second conductors 32 are positioned on the first projecting portion 211 and on the same plane. More specifically, the first conductors 31 and the second conductors 32 are positioned on a second upper surface 211u described below. When the first conductors 31 and the second conductors 32 are arranged as described above, the electronic component housing package 100 can be smaller and have a reduced height, and a greater number of wiring conductors 3 can be positioned on the surface of the frame 2. Therefore, a greater number of electronic components 9 can be mounted in the electronic component housing package 100. Also, connection to an external wiring board or electronic circuit can be provided with greater flexibility in wiring design.

No wiring conductors 3 may be positioned beyond the second conductors 32 in the x direction on the first projecting portion 211. In other words, no wiring conductors 3 may be positioned between the first-projecting-portion side surface 211s and the second conductors 32.

The first conductors 31 and/or the second conductors 32 may serve as power supply terminals, signal terminals, or ground terminals.

When the direction along the first frame side surface 21 is a second direction (in other words, y direction in the drawings; in the following description, the second direction is referred to also as the y direction for convenience), multiple first conductors 31 may be arranged along the y direction, and multiple second conductors 32 may be arranged along the y direction. This structure enables an increase in the number of wiring conductors 3 positioned on the surface of the frame 2 without increasing the number of conductors arranged in the x direction.

In the above-described case, the multiple first conductors 31 may all have the same shape or include one or more first conductors 31 shaped differently from the remaining one or more first conductors 31. The multiple second conductors 32 may all have the same shape or include one or more second conductors 32 shaped differently from the remaining one or more second conductors 32. Any one of the first conductors 31 and the second conductors 32 may serve as a signal terminal.

As illustrated in FIG. 2, in an embodiment, the first conductors 31 and the second conductors 32 have equal intervals (intervals in the y direction in the drawings). However, the first conductors 31 and/or the second conductors 32 may have different intervals. For example, the first conductors 31 and/or the second conductors 32 may have suitable shapes and suitable intervals in accordance with respective one or more connection members described below that are connected thereto.

One or more connection members described below may be connected to the wiring conductors 3. More specifically, a plurality of connection members of one type or a plurality of types of connection members may be connected to the wiring conductors 3. The same connection member may be connected to all of the first conductors 31. Alternatively, a flexible board (FPC (flexible printed circuits)) may be connected to one or more of the first conductors 31 while a connector is connected to the remaining one or more first conductors 31. For example, a connector may be connected to the first conductors 31 while a flexible board is connected to the second conductors 32. Alternatively, for example, the first conductors 31 and the second conductors 32 may be connected to different types of connectors.

For example, the first conductors 31 may all serve as signal terminals while the second conductors 32 all serve as ground terminals and/or power supply terminals. This structure allows the first conductors 31, which transmit signals, to be closer to the first region 1r than the second conductors 32 in plan view, thereby reducing the signal transmission distance to the electronic component 9. Therefore, high-frequency signals can be transmitted between the electronic component 9 and the first conductors 31 with reduced signal loss.

The frame 2 may include a second frame side surface 22 and a second projecting portion 222. The second frame side surface 22 may face the first frame side surface 21 in the x direction. The second projecting portion 222 projects outward from the second frame side surface 22 in the x direction.

The wiring conductors 3 may include one or more third conductors 33 and one or more fourth conductors 34. The fourth conductors 34 may be spaced from the third conductors 33 in the x direction. The third conductors 33 and the fourth conductors 34 may be positioned on the second projecting portion 222 and on the same plane. According to this structure, the wiring conductors 3 may be formed at a side opposite to a side of the first projecting portion 211 in the x direction, so that the number of wiring conductors 3 positioned on the surface of the frame 2 can be increased. Therefore, a greater number of electronic components 9 can be mounted in the electronic component housing package 100. Also, connection to an external wiring board or electronic circuit can be provided with greater flexibility in wiring design.

More specifically, the third conductors 33 and the fourth conductors 34 are positioned on a third upper surface 222u described below. Note that multiple third conductors 33 may be arranged along the y direction, and multiple fourth conductors 34 may be arranged along the y direction.

As illustrated in FIG. 2 and other drawings, the third conductors 33 and the fourth conductors 34 may have rectangular shapes including long sides along the x direction. The third conductors 33 and the fourth conductors 34 may have the same or different shapes.

As illustrated in FIG. 2, the base 1 may overlap the first projecting portion 211 in plan view. In other words, the base 1 supports at least a portion of the first projecting portion 211. According to this structure, when a connection member, such as a lead terminal, a flexible board (FPC), or a connector, is joined to the first conductors 31 and/or the second conductors 32, the first projecting portion 211 is less likely to receive a stress that causes deformation of or damage to the frame 2.

As illustrated in FIG. 2, the base 1 may include a first base side surface 11s positioned along the first frame side surface 21. The first projecting portion 211 may include the first-projecting-portion side surface 211s positioned along the first frame side surface 21. In this case, a distance L1 from the first frame side surface 21 to the first base side surface 11s in the first direction may be equal to or greater than one-half of a distance L2 from the first frame side surface 21 to the first-projecting-portion side surface 211s in the first direction. According to this structure, even when an end portion (that is, a portion including the first-projecting-portion side surface 211s) of the first projecting portion 211 receives a stress upon joining with a connection member, the base 1 efficiently supports the first projecting portion 211, so that the first projecting portion 211 and the frame 2 are less likely to be deformed. When the base 1 and a portion of a lower surface of the first projecting portion 211 that overlaps the base 1 are joined with a joining material, the first projecting portion 211 is even less likely to be deformed.

Note that the base 1 may include a second base side surface 12s positioned along the second frame side surface 22. The second projecting portion 222 may include a second-projecting-portion side surface 222s positioned along the second frame side surface 22.

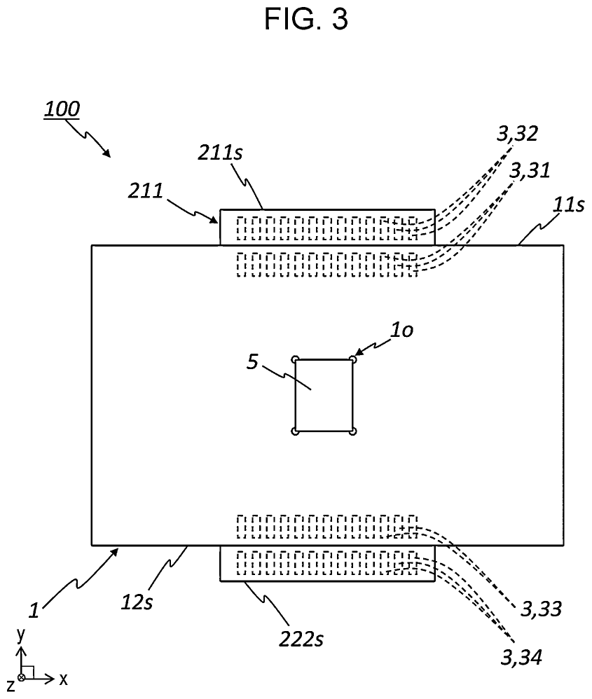

As illustrated in FIGS. 2 and 3, the base 1 may overlap the first conductors 31 in plan view. According to this structure, deformation of the first projecting portion 211 due to stress applied upon connection of a connection member to the first conductors 31 is less likely to occur. Note that, in FIG. 3, the first to fourth conductors 31 to 34 are illustrated in see-through view.

As illustrated in FIG. 3, the base 1 may be spaced from the second conductors 32 in plan view. In other words, the base 1 may be such that the base 1 does not overlap the second conductors 32 in plan view. More specifically, the base 1 may be such that the base 1 overlaps only the first conductors 31 in plan view. This structure enables a reduction in the size of the base 1, so that the electronic component housing package 100 can be smaller. According to the above-described structure, the lower surface of the first projecting portion 211 is partially exposed, so that the wiring conductors 3 can be formed also on the lower surface of the first projecting portion 211.

The frame 2 may be made of a ceramic material. This facilitates formation of the wiring conductors 3 and metal wires on a surface of the frame 2 and inside the frame 2. Also, the electronic component 9 can be sealed airtightly.

The base 1 may be made of a metal material. This structure enables efficient dissipation of heat generated in the electronic component 9 mounted in the first region 1r to the outside of the electronic component housing package 100.

As illustrated in FIG. 2, the frame 2 may include a first upper surface 2u. The first projecting portion 211 may include a second upper surface 211u. The first conductors 31 and the second conductors 32 are positioned on the second upper surface 211u. The first upper surface 2u may be flush with the second upper surface 211u. According to this structure, the electronic component housing package 100 can have a smaller dimension in the z direction. Therefore, the electronic module 10 can be smaller. The first upper surface 2u can be defined as a surface on which a joining region 26r described below is positioned. In other words, a surface of the frame 2 on which a lid body 8 or a seal ring 6 is joined may be defined as the first upper surface 2u. Note that, in FIG. 2, the seal ring 6 is omitted.

As illustrated in FIG. 2, the first upper surface 2u may include the joining region 26r to which the lid body 8 or the seal ring 6 is joined. In this case, the joining region 26r may be spaced from the first conductors 31 and the second conductors 32. According to this structure, when the seal ring 6 or the lid body 8 is joined to the first upper surface 2u with a joining material, the joining material is less likely to come into contact with the first conductors 31 and/or the second conductors 32 and cause short-circuiting of the wiring conductors 3.

As illustrated in FIG. 2, the first projecting portion 211 may include the first-projecting-portion side surface 211s positioned along the first frame side surface 21. In this case, a distance D1 between the joining region 26r and the first conductors 31 in the x direction may be greater than a distance D2 between the first-projecting-portion side surface 211s and the second conductors 32 in the x direction. According to this structure, when the seal ring 6 or the lid body 8 is joined to the first upper surface 2u with the joining material, the possibility that the joining material will come into contact with the first conductors 31 and/or the second conductors 32 and cause short-circuiting of the wiring conductors 3 can be more effectively reduced. Also, the wiring conductors 3 positioned on the surface of the frame 2 can be increased. The first projecting portion 211 can have a smaller dimension in the x direction, so that the electronic component housing package 100 can be smaller.

As illustrated in FIG. 3, the electronic component housing package 100 may further include a transparent member 5 joined to the base 1. The base 1 may include a through-hole 1o that extends through the base 1 in the first region 1r. In this case, the transparent member 5 may overlap the through-hole 1o. This structure enables optical transmission between the electronic component 9 housed in the electronic component housing package 100 and the inside/outside of the electronic component housing package 100 when the electronic component 9 is an optical semiconductor device, such as an LD (laser diode) or a PD (photodiode), an optical sensor, or the like.

The through-hole 1o may have a rectangular shape, a circular shape, or a substantially rectangular shape with rounded corners in plan view. Note that the base 1 may include more than one through-holes 1o.

More specifically, the transparent member 5 may be positioned in the through-hole 1o. According to this structure, the electronic component housing package 100 can have a smaller dimension in the z direction compared to when the transparent member 5 is joined to the lower surface of the base 1. Therefore, the electronic component housing package 100 and the electronic module 10 can be smaller.

The base 1 may be such that a portion of the through-hole 1o includes a step portion 25 that projects toward the inner region of the through-hole 1o. This structure enables the transparent member 5 to be joined to the step portion 25. Therefore, joining of the transparent member 5 in the through-hole 1o is easier than when no step portion 25 is provided.

A connection member may be connected to the wiring conductors 3. The connection member may be, for example, a lead terminal, a flexible board, a printed board on which an electronic circuit is formed (PCB (printed circuit board)), or a connector. An end of the connection member may be connected to a flexible board or a printed circuit board on which an electronic circuit is formed.

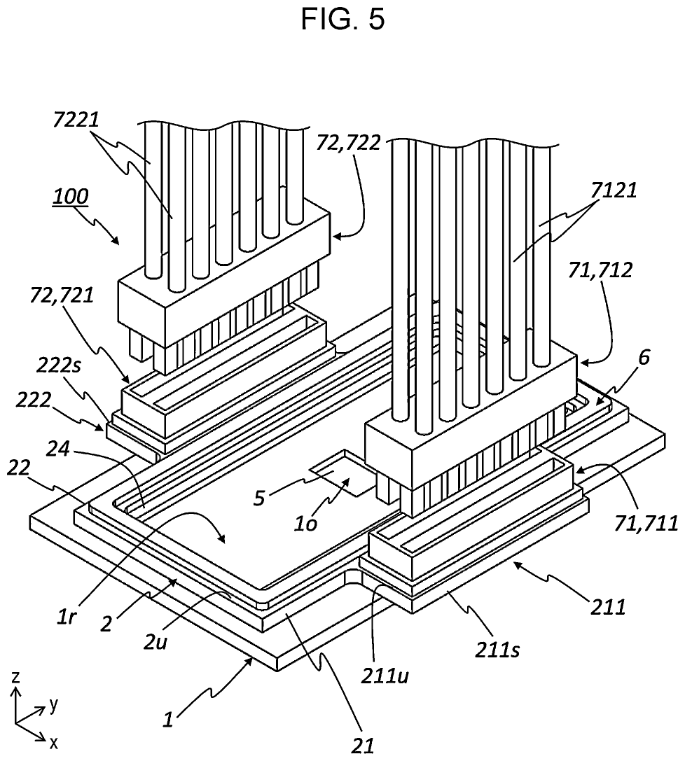

More specifically, as illustrated in FIG. 5, the electronic component housing package 100 may further include a first connector 71. The first connector 71 may be positioned on the first projecting portion 211. The first connector 71 may include at least two or more wiring terminals. In this case, the wiring terminals may be electrically connected to respective ones of the first conductors 31 and the second conductors 32. This structure facilitates the connection of a plurality of wires to the electronic component housing package 100.

More specifically, the first connector 71 may include a first socket 711 and a first plug 712. In this case, the first socket 711 may be positioned on the first projecting portion 211. This structure facilitates attachment and removable of the first connector 71. The structure also allows the electronic module 10 or the first connector 71 to be easily replaced when the electronic module 10 or the first connector 71 is defective. Note that the first plug 712 may include one or more first wiring cables 7121.

As illustrated in FIG. 5, the electronic component housing package 100 may further include a second connector 72. The second connector 72 may be positioned on the second projecting portion 222. The second connector 72 may include at least two or more wiring terminals. In this case, the wiring terminals may be electrically connected to respective ones of the third conductors 33 and the fourth conductors 34. More specifically, the second connector 72 may include a second socket 721 and a second plug 722. In this case, the second socket 721 may be positioned on the second projecting portion 222. Note that the second plug 722 may include one or more second wiring cables 7221.

### Another Embodiment

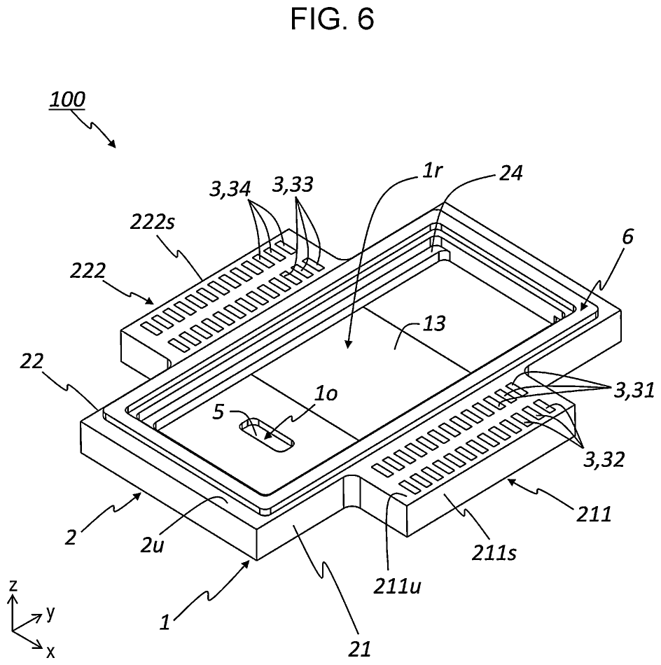

The electronic component housing package 100 according to embodiment will be described with reference to FIG. 6. Only portions of the structure of the other embodiment different from those of the structure of the above-described embodiments will be described. Other portions are denoted by the same reference signs as those of each embodiment, and description thereof will be omitted.

In the other embodiment illustrated in FIG. 6, a portion of the base 1 and the frame 2 are integrated together. More specifically, a metal plate is fitted to a portion of the base 1. According to this structure, a portion on which the electronic component 9 is mounted may be composed of a metal body 13 with high heat dissipation performance, so that the electronic component housing package 100 can be easily manufactured and can have increased heat dissipation performance. In this case, a portion of the base 1 other than the metal body 13 (in other words, a ceramic portion of the base 1) and the frame 2 may both be made of a ceramic material.

As in the other embodiment illustrated in FIG. 6, the transparent member 5 may be joined to a portion of the base 1 other than the metal body 13. In other words, the ceramic portion of the base 1 may include the through-hole 1o. Note that the transparent member 5 may also be joined to the metal body 13. In other words, the metal body 13 may include the through-hole 1o. Each of the ceramic portion and the metal body 13 of the base 1 may include the through-hole 1o.

### <Structure of Electronic Module>

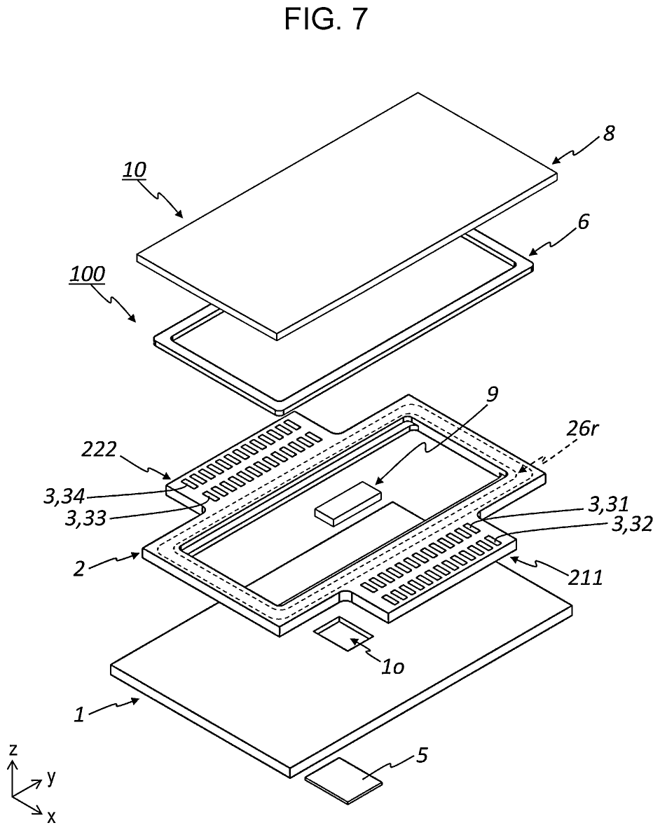

As illustrated in FIG. 7, the electronic module 10 according to an embodiment includes the electronic component 9, the lid body 8, and the electronic component housing package 100.

The electronic component 9 is positioned on the first region 1r. Examples of the electronic component 9 include an optical semiconductor device, such as an LD (laser diode) or a PD (photodiode), a semiconductor integrated circuit element, a sensor element, such as an optical sensor, and a power amplifier IC. The electronic component 9 may be formed using, for example, a semiconductor material, such as gallium arsenide or gallium nitride.

The electronic component 9 may be directly positioned on the first region 1r, or be indirectly positioned on the first region 1r with, for example, a sub-mount provided between the electronic component 9 and the first region 1r. The number of electronic components 9 is not limited to one, and may be two or more. For example, the electronic components 9 may include a light receiving element and a light emitting element.

The electronic module 10 may include an optical component, such as a collimator lens, a dironic filter, or a mirror. The optical component may be positioned on the first region 1r or on the shelf portion 24.

The lid body 8 is positioned on the frame 2. The lid body 8 protects the electronic component 9 together with the frame 2. The material of the lid body 8 may be, for example, a metal material, an alloy obtained by combining multiple metal materials, or a ceramic. Note that the transparent member 5 may be attached to the lid body 8.

The electronic module 10 may further include the seal ring 6 positioned between the lid body 8 and the frame 2. The seal ring 6 is positioned on the frame 2, and surrounds the electronic component 9 in plan view. Note that when the seal ring 6 is not provided on the frame 2, the lid body 8 may be joined to the frame 2 (that is, to the first upper surface 2u) with, for example, solder, a brazing material, glass, or an adhesive, such as a resin adhesive material.

Note that various combinations in each embodiment and each variation are not limited to the examples in the above-described embodiments. The embodiments and the variations may be combined with each other.

### REFERENCE SIGNS LIST

1 base
1r first region
1o through-hole
11s first base side surface
12s second base side surface
13 metal body
2 frame
2u first upper surface
21 first frame side surface
211 first projecting portion
211u second upper surface
211s first-projecting-portion side surface
22 second frame side surface
222 second projecting portion
222u third upper surface
222s second-projecting-portion side surface
24 shelf portion
25 step portion
26r joining region
3 wiring conductor
31 first conductor
32 second conductor
33 third conductor
34 fourth conductor
5 transparent member
6 seal ring
71 first connector
711 first socket
712 first plug
7121 first wiring cable
72 second connector
721 second socket
722 second plug
7221 second wiring cable
8 lid body
9 electronic component
10 electronic module
100 electronic component housing package

1. An electronic component housing package comprising:
a base comprising a first region;
a frame:
positioned on the base;
surrounding the first region; and
comprising a first frame side surface; and
a wiring conductor positioned on a surface of the frame,
wherein the frame comprises a first projecting portion projecting outward from the first frame side surface in a first direction, and
wherein the wiring conductor comprises:
a first conductor; and
a second conductor spaced outward from the first conductor in the first direction, and
wherein the first conductor and the second conductor are positioned on the first projecting portion and on a same plane.

2. The electronic component housing package according to claim 1,
wherein, when a direction along the first frame side surface is a second direction,
a plurality of the first conductors is arranged in the second direction, and a plurality of the second conductors is arranged in the second direction.

3. The electronic component housing package according to claim 1,
wherein the frame comprises:
a second frame side surface facing the first frame side surface in the first direction; and
a second projecting portion projecting outward from the second frame side surface in the first direction,
wherein the wiring conductor comprises:
a third conductor; and
a fourth conductor spaced from the third conductor in the first direction, and
wherein the third conductor and the fourth conductor are positioned on the second projecting portion and on a same plane.

4. The electronic component housing package according to claim 1,
wherein the base overlaps the first projecting portion in plan view.

5. The electronic component housing package according to claim 4,
wherein the base comprises a first base side surface positioned along the first frame side surface,
wherein the first projecting portion comprises a first-projecting-portion side surface positioned along the first frame side surface, and
wherein a distance L1 from the first frame side surface to the first base side surface in the first direction is equal to or greater than one-half of a distance L2 from the first frame side surface to the first-projecting-portion side surface in the first direction.

6. The electronic component housing package according to claim 4,
wherein the base overlaps the first conductor in plan view.

7. The electronic component housing package according to claim 6,
wherein the base is spaced from the second conductor in plan view.

8. The electronic component housing package according to claim 1,
wherein the frame is made of a ceramic material.

9. The electronic component housing package according to claim 8,
wherein the base is made of a metal material.

10. The electronic component housing package according to claim 1,
wherein the frame comprises a first upper surface,
wherein the first projecting portion comprises a second upper surface, the first conductor and the second conductor being positioned on the second upper surface, and
wherein the first upper surface is flush with the second upper surface.

11. The electronic component housing package according to claim 10,
wherein the first upper surface comprises a joining region, a lid body or a seal ring being joined to the joining region, and
wherein the joining region is spaced from the first conductor and the second conductor.

12. The electronic component housing package according to claim 11,
wherein the first projecting portion comprises a first-projecting-portion side surface positioned along the first frame side surface, and
wherein a distance D1 between the joining region and the first conductor in the first direction is greater than a distance D2 between the first-projecting-portion side surface and the second conductor in the first direction.

13. The electronic component housing package according to claim 1, further comprising:
a transparent member joined to the base,
wherein the base comprises a through-hole extending through the base in the first region, and
wherein the transparent member overlaps the through-hole.

14. The electronic component housing package according to claim 1, further comprising:
a first connector comprising at least two or more wiring terminals and positioned on the first projecting portion,
wherein each of the at least two or more wiring terminals is electrically connected to a respective one of the first conductor and the second conductor.

15. An electronic module comprising:
an electronic component positioned on the first region;
a lid body positioned on the frame; and
the electronic component housing package according to claim 1.
